(19) United States
(12) Patent Application Publication
(10) Pub. No.: US 2018/0090634 A1
(43) Pub. Date: Mar. 29, 2018

(54) SOLAR MODULE AND PHOTOVOLTAIC POWER GENERATION SYSTEM

(71) Applicant: KABUSHIKI KAISHA TOSHIBA, Tokyo (JP)

(72) Inventors: Soichiro Shibasaki, Nerima Tokyo (JP); Miyuki Shiokawa, Kawasaki Kanagawa (JP); Naoyuki Nakagawa, Setagaya Tokyo (JP); Sara Yoshio, Taito Tokyo (JP); Mutsuki Yamazaki, Yokohama Kanagawa (JP); Hiroki Hiraga, Saitama Saitama (JP); Kazushige Yamamoto, Yokohama Kanagawa (JP); Yuya Honishi, Yokohama Kanagawa (JP); Takeshi Niimoto, Kawasaki Kanagawa (JP)

(21) Appl. No.: 15/696,212

(22) Filed: Sep. 6, 2017

(30) Foreign Application Priority Data
Sep. 23, 2016 (JP) 2016-185746
Mar. 22, 2017 (JP) 2017-056527
Jun. 27, 2017 (JP) 2017-125121

(51) Int. Cl. H01L 31/05; H01L 31/043; H01L 31/0725; H01L 31/054; H02S 40/34; H01L 31/0687

(52) U.S. Cl. CPC H01L 31/0504; H01L 31/043; H01L 31/0687; H01L 31/054; H02S 40/34; H01L 31/0725

(57) ABSTRACT

A solar module of an embodiment includes: a first solar panel having a plurality of first submodules each including a plurality of first solar cells; and a second solar panel layered with the first solar panel, the second solar panel having a plurality of second submodules each including a plurality of second solar cells. The first solar panel is provided on a side where light is incident. The first solar panel and the second solar panel are electrically connected in parallel. The plurality of first solar cells included in each of the plurality of first submodules is electrically connected in series. The plurality of first submodules is electrically connected in parallel. The plurality of second solar cells included in each of the plurality of second submodules is electrically connected in series. The plurality of second submodules is electrically connected in parallel.

### CROSS-REFERENCE TO RELATED APPLICATION

This application is based upon and claims the benefit of priority from Japanese Patent Applications No. 2016-185746, filed on Sep. 23, 2016, 2017-056527, filed on Mar. 22, 2017 and 2017-125121 filed on Jun. 27, 2017; the entire contents of which are incorporated herein by reference.

### FIELD

Embodiments described herein relate to a solar module and a photovoltaic power generation system.

### BACKGROUND

An example of a high-efficiency solar cell is a multi-junction (tandem) solar cell. A cell effective for each wavelength range can be used so that high efficiency is expected in comparison to a uni-junction. A chalcopyrite solar cell including, for example, CIGS (a compound of copper, indium, gallium, and selenium) is known to have high efficiency, and can be made wide-gap so as to be a candidate for a top cell. However, a connecting method has not been sufficiently examined for a module including solar cells having a different bandgap, joined.

### BRIEF DESCRIPTION OF THE DRAWINGS

FIG. 1 is a perspective conceptual view of a solar module according to a first embodiment;

FIG. 2 is a schematic view of a first solar panel according to the first embodiment;

FIG. 3 is a schematic view of the first solar panel according to the first embodiment;

FIG. 4 is a schematic view of a second solar panel according to the first embodiment;

FIG. 5 is a schematic view of the second solar panel according to the first embodiment;

FIG. 6 is a perspective conceptual view of a solar module according to a second embodiment;

FIG. 7 is a schematic view of a first solar panel according to the second embodiment;

FIG. 8 is a schematic view of a second solar panel according to the second embodiment;

FIG. 9A is a sectional conceptual view of a solar module according to the second embodiment;

FIG. 9B is a sectional conceptual view of another solar module according to the second embodiment;

FIG. 9C is a sectional conceptual view of another solar module according to the second embodiment;

FIG. 10A is a sectional conceptual view of another solar module according to the second embodiment;

FIG. 10B is a sectional conceptual view of another solar module according to the second embodiment;

FIG. 10C is a sectional conceptual view of another solar module according to the second embodiment;

FIG. 11 is a schematic view of a second solar panel according to the second embodiment;

FIG. 12 is a schematic view of a second solar panel according to the second embodiment;

FIG. 13 is a schematic view of a second solar panel according to the second embodiment;

FIG. 14 is a schematic view of a second solar panel according to the second embodiment; and

FIG. 15 is a conceptual diagram of a photovoltaic power generation system according to a third embodiment.

### DETAILED DESCRIPTION

A solar module of an embodiment includes: a first solar panel having a plurality of first submodules each including a plurality of first solar cells; and a second solar panel layered with the first solar panel, the second solar panel having a plurality of second submodules each including a plurality of second solar cells. The first solar panel is provided on aside where light is incident. The first solar panel and the second solar panel are electrically connected in parallel. The plurality of first solar cells included in each of the plurality of first submodules is electrically connected in series. The plurality of first submodules is electrically connected in parallel. The plurality of second solar cells included in each of the plurality of second submodules is electrically connected in series. The plurality of second submodules is electrically connected in parallel.

Embodiments of the present disclosure will be described in detail below with respect to the drawings.

### First Embodiment

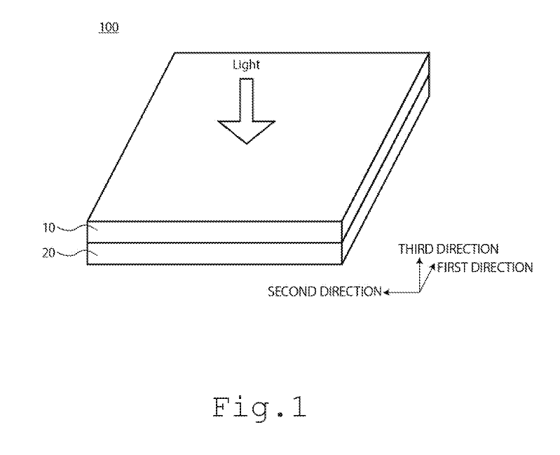

A solar module according to a first embodiment has a structure including at least two solar panels layered. The at least two solar panels are electrically connected in parallel. As illustrated in a perspective conceptual view of FIG. 1, a solar module 100 according to the present embodiment has a first solar panel 10 and a second solar panel 20. The first solar panel 10 and the second solar panel 20 are layered in a third direction. The first solar panel 10 and the second solar panel 20 are electrically connected in parallel. A depth direction of the solar module 100 is defined as a first direction and a width direction of the solar module 100 is defined as a second direction. The first direction and the second direction are cross or orthogonal to each other, a plane including the first direction and the second direction is parallel to a panel face of the solar module 100. The first direction is orthogonal to the second direction and the third direction, and the second direction is orthogonal to the first direction and the third direction. Note that, the orthogonality includes similar structures without departing from the scope of equivalents of the present disclosure. A third direction is perpendicular to the first direction and perpendicular to the second direction. In embodiments, two solar panels are stacked. The embodiments may include a solar cell module having three or more solar panels are stacked.

Electric power generated by each of the first solar panel 10 and the second solar panel 20 is converted so as to be stored, be transmitted, or be consumed. The electric power generated by the first solar panel 10 and the electric power generated by the second solar panel 20 both are required to be converted by a power conversion device (a converter) for the storage, the transmission, and the consumption. When different converters for the first solar panel 10 and the second solar panel 20 each perform conversion, a dual-system converter is required. An increase of the number of the converters increases power generation costs. Therefore, even when the number of the panels to be layered is at least two, the solar module 100 has a power output terminal for only a single system because each panel is electrically connected in parallel. The increase of the power generation costs with conversion efficiency improved is unfavorable in terms of recovery of an investment fund even when the conversion efficiency improves due to the multi-junction.

(First Solar Panel)

The first solar panel 10 is provided on the side of a top of the solar module 100, namely, on the side where light is incident. The first solar panel 10 has a plurality of solar cells having a wide bandgap light-absorbing layer. Examples of the wide bandgap light-absorbing layer include at least one type of a compound semiconductor, a perovskite compound, a transparent oxide semiconductor, and amorphous silicon. The bandgap of the wide bandgap light-absorbing layer is 1.4 eV or more, preferably, 1.4 to 2.7 eV, and, more preferably, 1.6 eV to 2.0 eV. The first solar panel 10 according to the embodiment is excellent in conversion efficiency even as a single body. Therefore, the first solar panel 10 according to the embodiment is also preferably used as a solar cell being a single body, without another solar panel layered therewith. The bandgap of the light-absorbing layer is acquired by measuring transmittance and reflectance, acquiring an absorption coefficient, using direct transition and indirect transition, and then performing fitting.

The first solar panel 10 includes a plurality of first submodules including a plurality of first solar cells 11. Each of the first submodules 11A includes a plurality of first solar cells 11. A plurality of first solar cells 11 are configured that the first direction is a longitudinal direction of the first solar cell 11. The plurality of first solar cells 11 included in the plurality of first submodules 11A is arranged in parallel in the second direction. The plurality of first solar cells 11 arranged in parallel in the second direction is electrically connected in series. The plurality of the first submodules 11A is electrically connected in parallel. A configuration including the first solar cells 11 connected in series and in parallel is adopted so that the conversion efficiency of the solar module 100 can improve. The cell number and cell sizes of the first solar cells 11 and the output voltage of the first solar panel 10 are adjusted in the first solar panel 10 according to the embodiment in order to achieve the object.

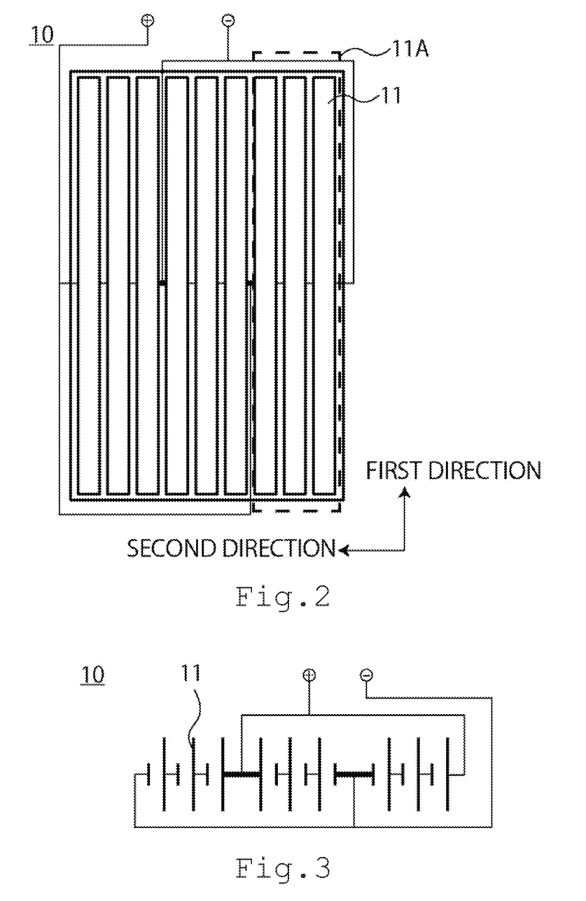

FIG. 2 is a schematic view illustrating the first solar panel 10. One of the first submodules 11A is surrounded by broken line. FIG. 3 is a schematic view illustrating, as a circuit, the first solar panel 10 illustrated in the schematic view of FIG. 2. In the schematic views of FIGS. 2 and 3, a fine line linking the first solar cells 11 is electric wiring connecting the first solar cells 11 in series. In the schematic views of FIGS. 2 and 3, a thick line linking the first solar cells 11 is electric wiring connecting the first solar cells 11 in parallel. FIGS. 2 and 3 illustrate a configuration including a trio of the first submodules 11A each having a trio of the solar cells 11 connected in series, connected in parallel. In the schematic views of FIGS. 2 and 3, the first solar cells 11 are arranged so as to alternate the first submodules 11A in polarity, but the first solar cells 11 may be arranged so as to allow the first submodules 11A to agree with each other in electrical polarity, and furthermore wiring for parallel connection may be provided.

(Second Solar Panel)

The second solar panel 20 is provided on the side of a bottom of the solar module 100, namely, on the side opposite to the side where the light is incident. The second solar panel 20 has a plurality of solar cells having a narrow bandgap light-absorbing layer. Examples of the narrow bandgap light-absorbing layer include a compound semiconductor and Ge. The bandgap of the narrow bandgap light-absorbing layer is less than 1.4 eV, preferably, 0.7 to 1.4 eV, and, more preferably, 0.7 to 1.2 eV. The second solar panel 20 according to the embodiment is excellent in conversion efficiency even as a single body. Therefore, the second solar panel 20 according to the embodiment is also preferably used as a solar cell being a single body, without another solar panel layered therewith.

The second solar panel 20 has a plurality of second submodules 21A including a plurality of second solar cells 21. Each of the second submodules 21A includes a plurality of second solar cells 21. A plurality of second solar cells 21 is configured that the first direction is a longitudinal direction of the first solar cell 21. The plurality of second solar cells 21 included in the second submodules 21A arranged in parallel in the second direction. The plurality of the second solar cells 21 arranged in parallel is electrically connected in series. The plurality of the second submodules 21A is electrically connected in parallel. A configuration including the second solar cells 21 connected in series and in parallel is adopted and the output voltage of the first solar panel 10 and the output voltage of the second solar panel 20 are adjusted so that the conversion efficiency of the solar module 100 can improve. The cell number and cell sizes of the second solar cells 21 and the output voltage of the second solar panel 20 are adjusted in the second solar panel 20 according to the embodiment in order to achieve the object.

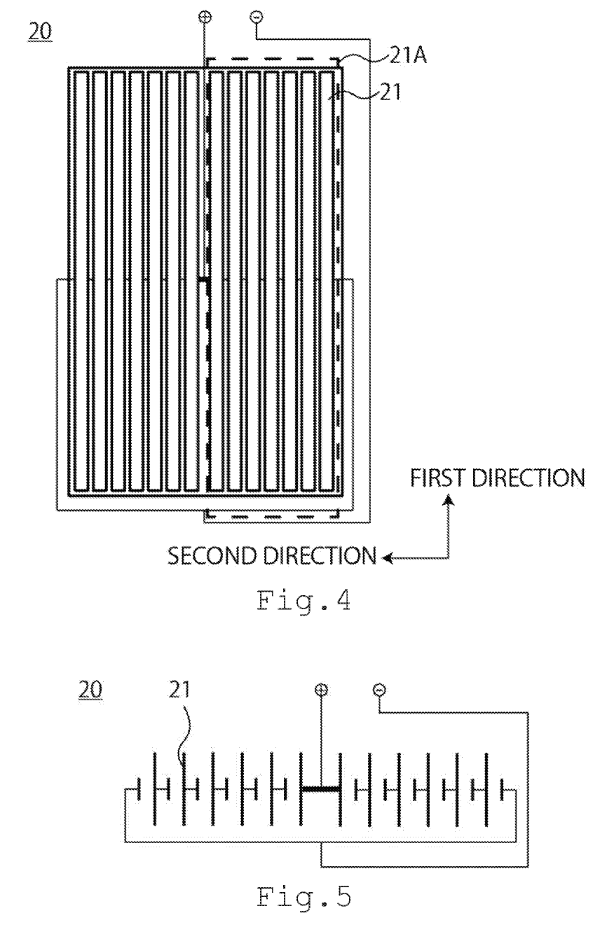

FIG. 4 is a schematic view illustrating the second solar panel 20. One of the second submodules 21A is surrounded by broken line. FIG. 5 is a schematic view illustrating, as a circuit, the second solar panel 20 illustrated in the schematic view of FIG. 4. In the schematic views of FIGS. 4 and 5, a fine line linking the second solar cells 21 is electric wiring connecting the second solar cells 21 in series. In the schematic views of FIGS. 4 and 5, a thick line linking the second solar cells 21 is electric wiring connecting the second solar cells 21 in parallel. FIGS. 4 and 5 illustrate a configuration including a pair of the second submodules 21A each having a sextuplet of the solar cells 21 connected in series, connected in parallel. In the schematic views of FIGS. 4 and 5, the second solar cells 21 are arranged so as to alternate the second submodules 21A in polarity, but the second solar cells 21 may be arranged so as to allow the second submodules 21A to agree with each other in polarity, and furthermore wiring for parallel connection may be provided.

A connecting mode of the solar cells will be described in more detail below. The difference between the output voltage of the first solar panel 10 and the output voltage of the second solar panel 20 is preferably small because the first solar panel 10 and the second solar panel 20 are connected in parallel. Thus, preferably, the plurality of first solar cells 11 is electrically connected in series and the plurality of second solar cells 21 is electrically connected in series. Varying the series connection number of the solar cells, can make the output voltages of the first solar panel 10 and the second solar panel 20 in agreement. The difference between the output voltage of the first solar panel 10 and the output voltage of the second solar panel 20 is preferably 2.0 V or less. With the difference of the output voltages as small as possible, loss due to the difference between the output voltage of the first solar panel 10 and the output voltage of the second solar panel 20, is favorably small in electrically connecting the first solar panel 10 and the second solar panel 20 in parallel. Therefore, the difference between the output voltage of the first solar panel 10 and the output voltage of the second solar panel 20 is more preferably 1.5 V or less or 1.0 V or less, and, further preferably, 0.5 V or less. The voltage difference between a maximum output point of the first solar panel 10 and a maximum output point of the second solar panel 20, is preferably 2.0 V or less, 1.5 V or less, or 1.0 V or less, and, more preferably, 0.5 V or less.

All the solar cells are electrically connected in series in consideration of the open voltages of the solar cells so that the difference between the output voltage of the first solar panel 10 and the output voltage of the second solar panel 20 can decrease. However, the first solar cells 11 of the first solar panel 10 each are required to have a transparent electrode for each electrode on the side of an upper portion and on the side of a lower portion. The transparent electrode has resistance larger than that of a metal electrode. Therefore, only electrically connecting the first solar cells 11 in series and electrically connecting the second solar cells 21 in series each reduce the cell number and increase the area of each cell. As a result, the resistance of the transparent electrodes in each cell increases so that the conversion efficiency of each solar cell decreases.

When the width of the first solar cells 11 in the second direction is adjusted and all the first solar cells 11 are connected in series in consideration of the resistance of the transparent electrodes, disagreement occurs with the output voltage of the second solar panel 20. For example, the first solar panel 10 including one solar cell, considerably differs from the second solar panel 10 in power generation voltage.

Thus, as described above, electrically connecting the submodules each including the solar cells electrically connected in series, in parallel, preferably increases the conversion efficiency of each of the first solar cells 11 and the second solar cells 21 and additionally decreases the difference between the output voltage of the first solar panel 10 and the output voltage of the second solar panel 20. With the above configuration, the number of the solar cells (a range) is first adjusted so as to acquire a size of each solar cell excellent in conversion efficiency. Based on the number, the series number and the parallel number of the first solar cells 10 and the series number and the parallel number of the second solar cells 21 are selected in order to make the output voltages of the first solar panel 10 and the second solar panel 20 the same or close to each other. The following expressions are preferably satisfied:

N₁=S₁×P₁

N₂=S₂×P₂

0.9≦(Voc₁×S₁)/(Voc₂×S₂)≦1.1

where N₁ represents the cell number, Voc₁ represents the open voltage, S₁ represents the series number, and P₁ represents the parallel number for the first solar cells 11, and N₂ represents the cell number, Voc₂ represents the open voltage, S₂ represents the series number, and P₂ represent the parallel number for the second solar cells 21.

The submodules each including the solar cells electrically connected in series, are electrically connected in parallel so that power loss is low even when the first solar panel 10 and the second solar panel 20 are electrically connected in parallel. Thus, the solar module 100 having high conversion efficiency can be acquired. The parallel number of the plurality of submodules is preferably equal to or less than 10 in the first solar panel 10 and the second solar panel 20. When the parallel number is small, the area of the transparent electrode per solar cell 11 is large so that power generation efficiency degrades due to an increase of the resistance resulting from the transparent electrode. When the parallel number is excessive, the number of the solar cells 11 in the panel increases and a non-power generation region, such as wiring, increases so that the power generation efficiency degrades. The parallel number may vary as appropriate by size of the first solar panel 10 or demanded character. For example, if size of the first solar panel 10 is larger, the parallel number increases from above mentioned parallel number.

The series number of the first solar cells 10 included in each of the first submodules 11A and the series number of the second solar cells 20 included in each of the second submodules 21A preferably differ from each other. Varying the series numbers can reduce the difference between the output voltage of the first solar panel 10 and the output voltage of the second solar panel 20. The first solar panel 10 and the second solar panel 20 each have the light-absorbing layer having the individual bandgap so that the open voltage of each first solar cell 10 in the first solar panel 11 and the open voltage of each second solar cell 21 in the second solar panel 20 differ from each other. The solar module 100 according to the embodiment includes the first solar panel 10 and the second solar panel 20 connected in parallel. Thus, when there is a difference between the operation voltages of both of the panels, each power to be output from the parallel connection is based on a voltage approximately being a lower operation voltage so that power loss occurs in an amount of the difference between the voltages. Therefore, when a connecting structure having the same series number is applied in the first solar panel 10 and the second solar panel 20, a large difference occurs between the output voltages of the first solar panel 10 and the second solar panel 20, due to the difference between the open voltage of each first solar cell 11 and the open voltage of each second solar cell 21. The output voltages of the solar panels are related to the open voltages of the solar cells and the series numbers thereof. Since the first solar cells 11 and the second solar cells 21 differ from each other in open voltage, the series number of the first solar cells 11 included in the first submodules 11A and the series number of the second solar cells 21 included in the second submodules 21A preferably differ from each other.

Here, the first solar panel 10 includes the first solar cells 11 having the light-absorbing layer including CGSS (Cu_{0.95}GaSe_{1.95}S_{0.05}) having an open voltage (Voc) of 0.95 V. The second solar panel 20 includes the second solar cells 21 having the light-absorbing layer including polycrystalline CIGS (Cu_{0.93}Ga_{0.3}In_{0.7}Se₂) having Voc being 0.71 V. The solar module 100 including the first solar panel 10 and the second solar panel 20 layered will be exemplarily described.

The number of the first solar cells 11 having the light-absorbing layer including the CGSS, is 168. The number of the first solar cells 11 electrically connected in series is 42, and the number of the first submodules connected is four. The four first submodules 11A are electrically connected in parallel. The CGSS having Voc being 0.95 V is used so that the first solar panel 10 has Voc being 39.9 V. The second solar panel 20 is made in agreement with Voc being 39.9 V in the first solar panel 10. The number of the second solar cells 21 having the light-absorbing layer including the CIGS, is 168 (183). The number of the second solar cells 21 electrically connected in series is 56 (61), and the number of the second submodules 21A connected is three. The three second submodules 21A are electrically connected in parallel. The CIGS having Voc being 0.71 V (a single body value, Voc changes to 0.66 V after the first solar panel 10 is mounted) is used so that the second solar panel 20 has Voc being 39.8 V (the single body value, Voc changes to 40.3 V after the first solar panel 10 is mounted). Voc to be acquired of the first solar panel 10 and Voc to be acquired of the second solar panel 20 are considerably close to each other. Thus, the output voltages of the respective panels are also close to each other so that the conversion efficiency of the solar module 100 improves. Typically, setting is preferably made so as to reduce a Voc difference upon maximum output, in consideration of Voc and FF of a bottom panel in mounting a top panel.

### Second Embodiment

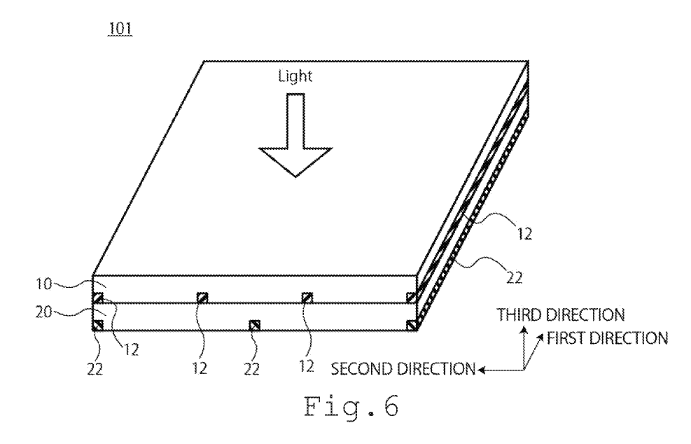

A solar module according to a second embodiment has a structure including at least two solar panels layered. The at least two solar panels are electrically connected in parallel. As illustrated in a perspective conceptual view of FIG. 6, the solar module 101 according to the present embodiment has a first solar panel 10 and a second solar panel 20. The first solar panel 10 and the second solar panel 20 are layered in a third direction. The first solar panel 10 and the second solar panel 20 are electrically connected in parallel. The first solar panel 10 has a first busbar 12 connecting first submodules 11A including first solar cells 11 in the first solar panel 10 in parallel. The second solar panel 20 has a second busbar 22 connecting second submodules 21A second solar cells 21 in the second solar panel 20 in parallel. The descriptions common between the first embodiment and the second embodiment will be omitted.

(Busbar)

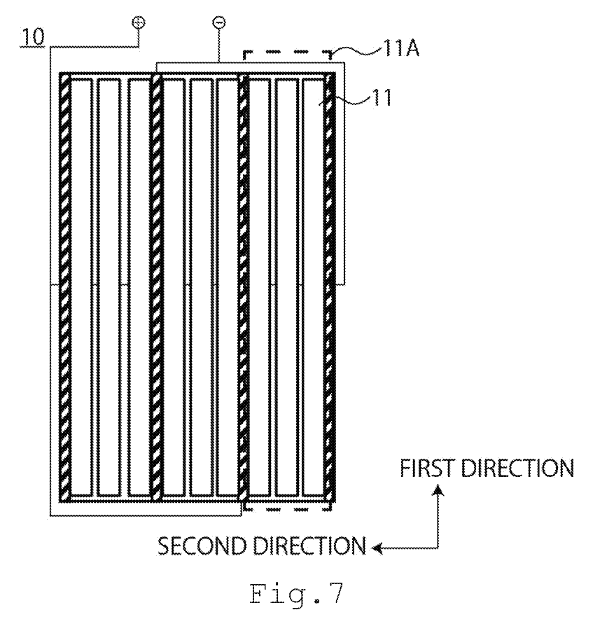

The first busbar 12 includes a conductive material, such as a metal plate or metal foil that connects a plurality of first submodules 11A including the first solar cells 11, in parallel in a second direction. FIG. 7 is a schematic view illustrating the first solar panel 10 according to the second embodiment. The first busbar 12 is metal wiring extending in a first direction. The first busbar 12 is arranged in parallel in the first solar panel 10 in the second direction. The first busbar 12 is arranged at both ends of the first solar panel 10 and between the plurality of first submodules 11A.

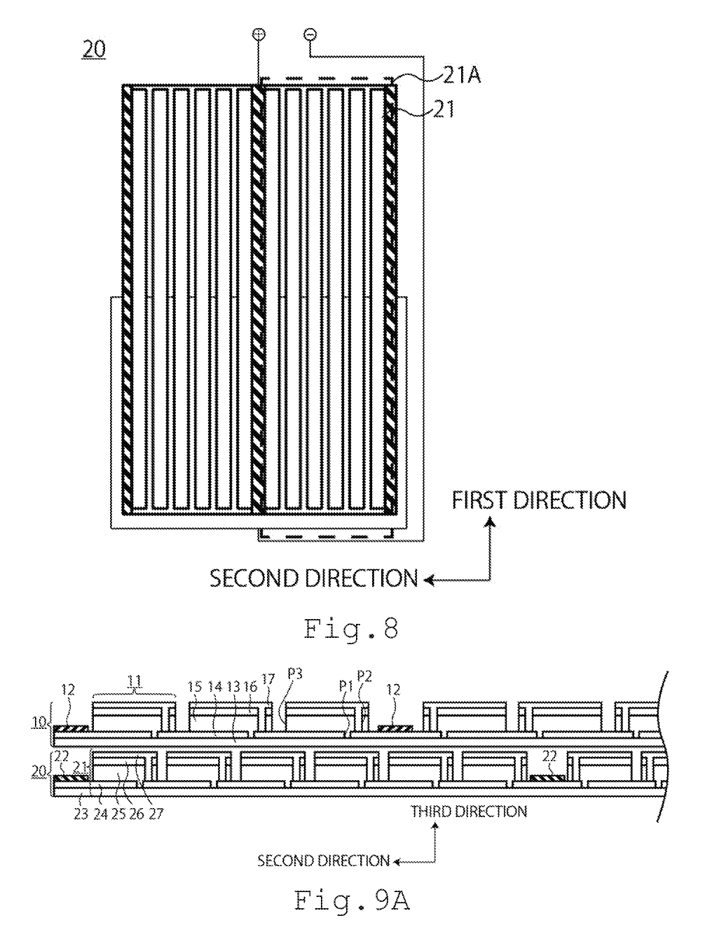

The second busbar 22 includes a metal plate that connects a plurality of second submodules 21A including the second solar cells 21, in parallel in the second direction. FIG. 8 is a schematic view illustrating the second solar panel 20 according to the second embodiment. The second busbar 22 is metal wiring extending in the first direction. The second busbar 22 is arranged in parallel in the second solar panel 20 in the second direction. The second busbar 22 is arranged at both ends of the second solar panel 20 and between the plurality of second submodules 21A.

The metal used for the first busbar 12 and the second busbar 22 is not particularly limited. For example, the first busbar 12 and the second busbar 22 are preferably wiring including at least one type metal of Al, Cu, Au, Ag, Mo, and W. The widths of the first busbar 12 and the second busbar 22 are preferably 1 to 5 mm. The first busbar 12 and the second busbar 22 excessively narrow cause resistance in receiving power and thus are unfavorable. Portions on which the first busbar 12 and the second busbar 22 are provided, are non-power generation regions. Therefore, the first busbar 12 and the second busbar 22 excessively wide decrease power generation capacity and thus are unfavorable. The heights of the first busbar 12 and the second busbar 22 are, but are not particularly limited to, preferably 2 mm or less or 1 mm or less because the heights excessively high cause difficulty in making wiring. Analysis of the solar module, such as the heights of the first busbar 12 and the second busbar 22, can be performed by upper face observation and sectional observation. As necessary, elemental analysis is performed.

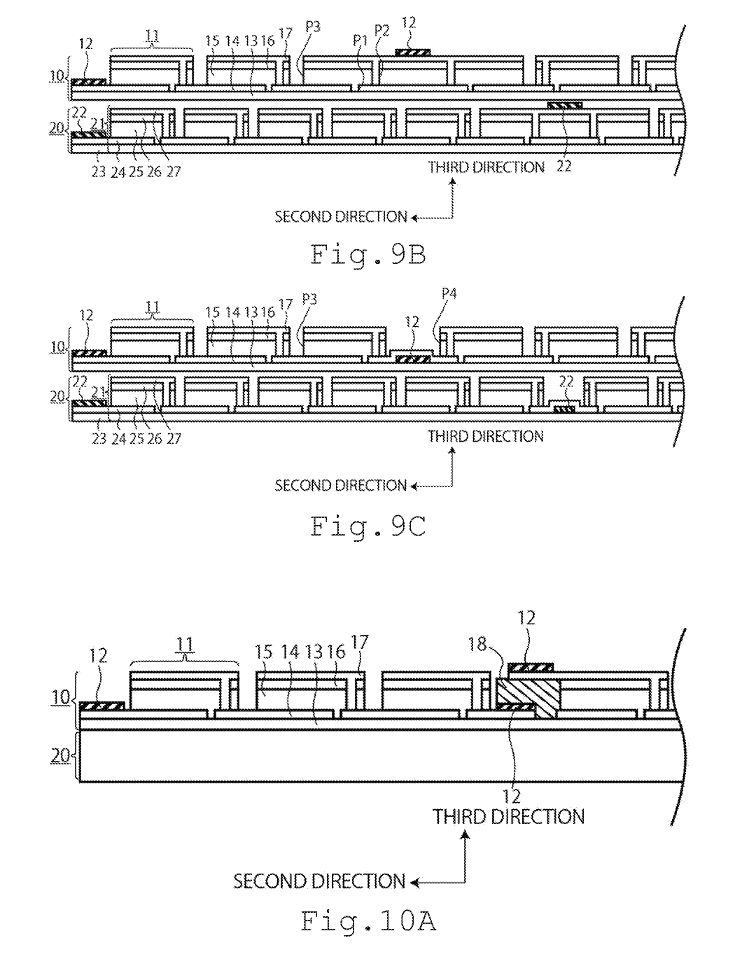

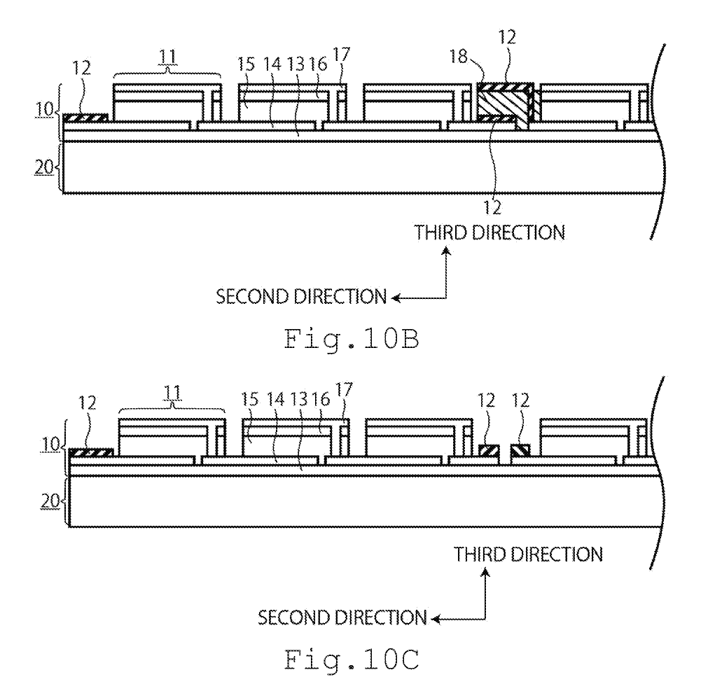

FIGS. 9A to 9C and FIGS. 10A to 10C illustrate a sectional schematic view of the solar module 101. The first solar panel 10 having the first solar cells 11 and the second solar panel 20 having the second solar cells 21 are provided in the schematic views of FIGS. 9A to 9C. The first solar panel 10 illustrated in the schematic views of FIGS. 9A to 9C, includes the first busbar 12, a substrate 13, and the plurality of first solar cells 11 including a first electrode 14, a light-absorbing layer 15, a buffer layer 16, and a second electrode 17. The second solar panel 20 illustrated in the schematic views of FIGS. 9A to 9C, includes the second busbar 22, a substrate 23, and the plurality of second solar cells 21 including a first electrode 24, a light-absorbing layer 25, a buffer layer 26, and a second electrode 27. P1, P2, and P3 represent sections cut in patterns 1, 2, and 3, respectively. FIGS. 9A to 9C exemplify a substrate-type substrate configuration, but the first solar panel 10 and the second solar panel 20 may adopt a superstrate-type substrate configuration. When the superstrate-type substrate configuration is adopted, the substrate 13 can act as tempered glass on the side on which light is received so that weight saving of the solar module 101 is achieved. When the substrate-type substrate configuration is provided, after the production, the first solar panel 10 may be covered with resin as necessary and then be reversed so as to be layered on the second solar panel 20.

FIGS. 9A to 9C are the schematic views of three patterns. FIG. 9A illustrates a mode including the first busbar 12 provided on a first electrode 14 included in corresponding first solar cells 11 and the second busbar 22 provided on a first electrode 24 included in corresponding second solar cells 21. The first electrode 14 included in the corresponding first solar cells 11 is interposed between the first busbar 12 and the substrate 13, and the first electrode 24 included in the corresponding second solar cells 21 is interposed between the second busbar 22 and the substrate 23.

FIG. 9B illustrates a mode including the first busbar 12 provided on a second electrode 17 included in corresponding first solar cells 11, and the second electrode 17 is interposed between the first busbar 12 and the light-absorbing layer 15. A mode including the second busbar 22 provided on a second electrode 27 included in corresponding second solar cells 21, is provided, and the second electrode 27 is interposed between the second busbar 22 and the light-absorbing layer 25.

FIG. 9C illustrates a mode including the first busbar 12 provided on the substrate 13 included in the first solar cells 11, and the first busbar 12 is interposed between the substrate 13 and a corresponding first electrode 14. A mode including the second busbar 22 provided on the substrate 23 included in the second solar cells 21, is provided, and the second busbar 22 is interposed between the substrate 23 and a corresponding first electrode 24. A cut section of P4 is provided to both ends of each of the first busbar 12 and the second busbar 22 in the schematic view of FIG. 9C. When the busbar 12 and corresponding second electrodes 17 are allowed to have wiring in parallel, the section of P4 is not necessarily formed. In the modes illustrated in schematic views of FIGS. 9A to 9C, the first solar cells 11 are symmetrically arranged with the first busbar 12 centered, and the second solar cells 21 are symmetrically arranged so as to alternate the second submodules 21A in electric polarity with the second busbar 22 centered. In FIGS. 9A to 9C, the first solar cells 11 and the second solar cells 21 are exposed, and the exposure is preferably covered with, for example, resin.

FIGS. 10A to 10C are the schematic views of three patterns. The second solar panel 20 is omitted in the schematic views of FIGS. 10A to 10C. In modes illustrated in the schematic views of FIGS. 10A to 10C, the first solar cells 11 are arranged so as to have polarity in the same direction so that the first submodules 11A are in agreement with polarity. FIG. 10A illustrates the mode including the busbar 12 provided onto each of a corresponding first electrode 14 included in a first submodule 11A on the left side of the illustration and a corresponding second electrode 17 of a first submodule 11A on the right side of the illustration. A pair of the busbars 12 is at least partially superimposed in the third direction. The polarity of the busbar 12 on the corresponding first electrode 14 and the polarity of the busbar 12 of the corresponding second electrode 17 differ from each other. An insulating film 18 includes, for example, resin or SiO₂, and insulates the two busbars 12. FIG. 10B illustrates the mode including the busbar 12 provided onto each of a corresponding first electrode 14 included in the first submodule 11A on the left side of the illustration and the insulating film 18. The busbar 12 on the insulating film 18 is connected to one of the first electrodes 14 included in the first submodule 11A on the right side of the illustration. A pair of the busbars 12 is at least partially superimposed in the third direction. The polarity of the busbar 12 on the corresponding first electrode 14 and the polarity of the busbar 12 on the insulating film 18 differ from each other. FIG. 10C illustrates the mode including the busbar 12 provided onto each of a corresponding first electrode 14 included in the first submodule 11A on the left side of the illustration and a corresponding first electrode 14 included in the first submodule 11A on the right side of the illustration. A pair of the busbars 12 is arranged in parallel in the second direction. The polarity of the busbar 12 on the corresponding first electrode 14 included in the first submodule 11A on the left side of the illustration and the polarity of the busbar 12 on the corresponding first electrode 14 included in the first submodule 11A on the right side of the illustration, differ from each other. In FIGS. 10A to 10C, the first solar cells 11 are exposed, and the exposure is preferably covered with, for example, resin.

(Substrate)

Soda lime glass is preferably used as the substrates 13 and 23 according to the embodiment, and glass in general, such as quartz, white glass, or chemically strengthened glass, or resin, such as polyimide or acrylic, can be also used.

(First Electrode)

The first electrode 14 of each first solar cell 11 according to the embodiment, is an electrode of each first solar cell 10. The first electrode 14 is, for example, a transparent electrode including a semiconductor film formed on the substrate 13. The first electrode 14 is interposed between the substrate 13 and the light-absorbing layer 15. The first electrode 14 may include a thin metal film. A semiconductor film including at least indium-tin oxide (ITO) can be used for the first electrode 14. A layer including an oxide, such as SnO₂, TiO₂, carrier-doped ZnO:Ga, or ZnO:Al, may be layered on the ITO on the side of the light-absorbing layer 15 ITO and SnO₂ may be layered from the side of the substrate 13 to the side of the light-absorbing layer 15, or ITO, SnO₂, and TiO₂ may be layered from the side of the substrate 13 to the side of the light-absorbing layer 15. A layer of the first electrode 14 in contact with the light-absorbing layer 15, is preferably an oxide layer including any of ITO, SnO₂, and TiO₂. A layer including an oxide, such as SiO₂, is further provided between the substrate 13 and the ITO. Sputtering is performed to the substrate 13 so as to produce the first electrode 14. The film thickness of the first electrode 14 is, for example, 100 to 1000 nm. When a solar cell according to the embodiment is used for a multi-junction solar cell, preferably, the solar cell according to the embodiment is provided on the side of a top cell or on the side of a middle cell and the first electrode 14 is a semiconductor film having translucency. The first electrode 24 of each second solar cell 21 may be the same as the first electrode 14 of each first solar cell 11, or may be a metal film, such as Mo or W.

(Light-Absorbing Layer)

The light-absorbing layer 15 of each first solar cell 11 according to the embodiment, is at least one type layer of a compound semiconductor, a perovskite compound, a transparent oxide semiconductor and amorphous silicon. The light-absorbing layer 15 is a layer that forms a p-n junction with the buffer layer 16. The buffer layer 16 is n-type when the light-absorbing layer 15 is p-type, whereas the buffer layer is p-type when the light-absorbing layer 15 is n-type. The light-absorbing layer 15 is interposed between the first electrode 14 and the buffer layer 16. When the light-absorbing layer 15 is homojunction-type, the buffer layer 16 may be omitted.

A compound semiconductor layer having a chalcopyrite structure, such as CuGaSe₂, Cu(Al, Ga)(S, Se)₂, CuGa(S, Se)₂, or Cu(In, Ga)(S, Se)₂ or a compound semiconductor layer, such as CdTe. (Cd, Zn, Mg)(Te, Se, S), or (In, Ga)₂(S, Se, Te)₃ can be used as the light-absorbing layer 15. The film thickness of the light-absorbing layer 15 is, for example, 800 to 3000 nm.

A transparent oxide semiconductor, such as Cu₂O can be used as the light-absorbing layer 15.

A combination of elements can easily adjust a bandgap in size to be a target value. The target value of the bandgap is, for example, 1.0 to 2.7 eV.

The light absorbing layer 15 provided on the side of a top cell and having a large band gap is preferable because power generation in the second solar cell at the bottom side increases due to have wider band gap in the light absorbing layer 15 provided on the side of a top cell. The light absorbing layer 15 having more wider band gap, such as Cu₂O, (Cd, Zn, Mg) (Te, Se, S) or (In, Ga)₂(S, Se, Te)₃ can be preferably used.

Another layer including a perovskite compound denoted with CH₃NH₃PbX₃ (X is at least one kind of halogen) or amorphous silicon, can be used as the light-absorbing layer 15.

The light-absorbing layer 25 of each second solar cell 21 according to the embodiment, is preferably a layer including one selected from the group consisting of: a compound semiconductor, a transparent oxide semiconductor, perovskite compound or a compound including Ge. Examples of the compound semiconductor include a compound semiconductor having a chalcopyrite structure denoted with Cu(In, Ga)Se₂, CuInTe₂, Cu(In, Al)Se₂, or Ag(In, Ga)Se₂, a compound semiconductor layer having a kesterite structure denoted with CZTS(Cu₂ZnSnS₄) or a stannite structure denoted with CZTSS(Cu₂ZnSnSe₄₋ₓSₓ). The transparent oxide semiconductor includes CuO. The perovskite compound includes CH₃NH₃PbX₃ (X is at least one kind of halogen). The light-absorbing layer 25 of each second solar cell 21 is in common with the light-absorbing layer 15 of each first solar cell 21 except composition of compounds, for example. A band gap of the light absorbing layer 25 of the second solar cell 21 is narrower than that of the light absorbing layer 15 of the first solar cell 11.

(Buffer Layer)

The buffer layers 16 and 26 according to the embodiment each are an n-type or p-type semiconductor layer. The buffer layer 16 is interposed between the light-absorbing layer 15 and the second electrode 17, and the buffer layer 26 is interposed between the light-absorbing layer 25 and the second electrode 27. The buffer layer 16 is a layer in physically contact with a face of the light-absorbing layer 15 on the side opposite to the other face thereof facing the side of the first electrode 14, and the buffer layer 26 is a layer in physically contact with a face of the light-absorbing layer 25 on the side opposite to the other face thereof facing the side of the first electrode 24. The buffer layer 16 is a layer having a heterojunction with the light-absorbing layer 15, and the buffer layer 26 is a layer having a heterojunction with the light-absorbing layer 25. The buffer layers 16 and 26 each are preferably an n-type semiconductor or a p-type semiconductor having a Fermi level controlled to achieve a solar cell having a high open voltage.

When the light-absorbing layers 15 and 25 each are a chalcopyrite compound, a kesterite compound, or a stannite compound, for example, Zn_{1-y}M_{y}O₁₋ₓSₓ, Zn_{1-y-z}Mg_{z}M_{y}O, ZnO₁₋ₓSₓ, Zn_{1-z}Mg_{z}O (M is at least one element selected from the group consisting of B, Al, In, and Ga) or CdS can be used for the buffer layers 16 and 26. The thicknesses of the buffer layers 16 and 26 are preferably 2 to 800 nm. The buffer layers 16 and 26 are produced by, for example, sputtering or chemical bath deposition (CBD). When produced by the CBD, for example, the buffer layers 16 and 26 can be formed on the light-absorbing layers 15 and 25, respectively, by a chemical reaction between a metallic salt (e.g., CdSO₄), a sulfide (thiourea), and a complexing agent (ammonia) in a solution. When the chalcopyrite compound with a group IIIb element including no In, such as a CuGaSe₂ layer, an AgGaSe₂ layer, a CuGaAlSe₂ layer, or CuGa (Se, S)₂ layer, is used for the light-absorbing layer 15, CdS is preferable as the buffer layers 16 and 26.

When the light-absorbing layer 25 is Ge, for example, ZnOₓ is preferably used for the buffer layer 26.

When the light-absorbing layer 15 is the perovskite compound, the buffer layer 16 is an n-type layer being a so-called compact layer. A layer including at least one type oxide selected from titanium oxide, zinc oxide, and gallium oxide, is preferable as the compact layer.

When the light-absorbing layer 15 is amorphous silicon, the buffer layer 16 preferably includes amorphous SiC:H having a wide gap similar to the amorphous silicon.

(Oxide Layer)

The oxide layer according to the embodiment is a thin film which is preferably provided between the buffer layer 16 and the second electrode 17 and between the buffer layer 26 and the second electrode 27. The oxide layer is a thin film including any of Zn₁₋ₓMgₓO, ZnO_{1-y}S_{y}, and Zn₁₋ₓMgₓO_{1-y}S_{y} (0≦x, y<1). A mode including the oxide layer not necessarily covering the entire face of the buffer layer 16 facing the side of the second electrode 17 and the entire face of the buffer layer 26 facing the side of the second electrode 27, may be provided. For example, the oxide layer at least covers 50% of the face of the buffer layer 16 on the side of the second electrode 17 and 50% of the face of the buffer layer 26 on the side of the second electrode 27. Other examples include AlO_{z}, SiO_{z}, SiN_{z}, and Wurtzite-type AlN, GaN, and BeO. When the volume resistivity of the oxide layer is 1 Ωcm or more, the oxide layer has an advantage in that a leak current resulting from a low resistance component possibly present in the light-absorbing layer 15 can be inhibited. Note that, according to the embodiment, the oxide layer can be omitted. The oxide layer is an oxide particle layer, and preferably has a large number of cavities inside. The intermediate layer is not limited to the compounds and the physical properties thereof, and is at least a layer that contributes to, for example, improvement of the conversion efficiency of the solar cell. The intermediate layer may include a plurality of layers each having different physical properties.

(Second Electrode)

The second electrodes 17 and 27 according to the embodiment each are an electrode film allowing light, such as sunlight, to pass therethrough and having conductivity. The second electrode 17 is in physically contact with a face of the intermediate layer or buffer layer 16 on the side opposite to the other face thereof facing the side of the light-absorbing layer 15. The second electrode 27 is in physically contact with a face of the intermediate layer or buffer layer 26 on the side opposite to the other face thereof facing the side of the light-absorbing layer 25. The light-absorbing layer 15 and the buffer layer 16 joined together are interposed between the second electrode 17 and the first electrode 14. The light-absorbing layer 25 and the buffer layer 26 joined together are interposed between the second electrode 27 and the first electrode 24. The second electrodes 17 and 27 are produced by performing sputtering in an Ar atmosphere, for example. For example, ZnO:Al including a ZnO target containing alumina (Al₂O₃) in an amount of 2 wt % or ZnO:B having a dopant being B from diborane or triethylboron, can be used for the second electrodes 17 and 27.

(Third Electrode)

A third electrode according to the embodiment is an electrode for each first solar cell 11 and for each second solar cell 21, and is a metal film formed on a face of the second electrode 17 on the side opposite to the other face thereof facing the side of the light-absorbing layer 15 and on a face of the second electrode 27 on the side opposite to the other face thereof facing the side of the light-absorbing layer 25. A conductive metal film, such as Ni or Al, can be used as the third electrode. The film thickness of the third electrode is, for example, 200 to 2000 nm. When resistance values of the second electrodes 17 and 27 are low and series resistance components can be negligibly small, the third electrode can be omitted.

(Antireflection Film)

An antireflection film according to the embodiment is a film for facilitating light to be introduced into the light-absorbing layers 15 and 25, and is formed on each of the second electrodes 17 and 27, or on a face of the third electrode on the side opposite to the other face thereof facing the side of the light-absorbing layer 15, and on a face of the third electrode on the side opposite to the other face thereof facing the side of the light-absorbing layer 25. The antireflection film is preferably provided between the first solar panel 10 and the second solar panel 20. For example, MgF₂ or SiO₂ is preferably used as the antireflection film. Note that, according to the embodiment, the antireflection film can be omitted. The film thickness is required to be adjusted in response to a refractive index of each layer, and vapor deposition is preferably performed in an amount of 70 to 130 nm (80 to 120 nm). Note that, a dichroic mirror that reflects a shorter wavelength and transmits a longer wavelength, is preferably provided between the first solar panel 10 and the second solar panel 20 instead of the antireflection film. Providing the dichroic mirror is preferable in that the light-absorbing layer on the side of the top cell can be thinned.

A method of producing each first solar cell 11, and the sections P1, P2, and P3 cut in patterns 1, 2, and 3, respectively, will be simply described. The first electrode 14 is produced on the substrate 13 and then scribing is performed to the first electrode 14 so as to form the section of P1. Subsequently, the light-absorbing layer 15 and the buffer layer 16 are produced. The light-absorbing layer 15 is also formed over the section of P1. Scribing is performed to the light-absorbing layer 15 and the buffer layer 16 so as to form the section of P2. Subsequently, the second electrode 17 is formed on the buffer layer 16. The second electrode 17 is also formed over the section of P2. Then, scribing is performed to the light-absorbing layer 15, the buffer layer 16, and the second electrode 17 so as to form the section of P3. Then, each first solar cell 11 connected in series is acquired. The busbar 12 may be formed on the substrate 13 before the production of the first electrode 14, or may be formed before or after the scribing processing for the formation of the section of P3. A method of producing each second solar cell 21, and patterns 1, 2, and 3 are in common with the method of producing each first solar cell 21, and patterns 1, 2, and 3.

The first electrode 14 and the second electrode 17 of each first solar cell 11 both are transparent electrodes that allow light to pass therethrough, and tend to have resistance higher than that of a metal film electrode. Therefore, when the areas of the first electrode 14 and the second electrode 17 are large, influence of the high resistance of the electrodes becomes conspicuous. Solar panels are approximately 1200×600 mm in small size and are approximately 1600×1000 mm in large size. The solar panel 10 has a large area so that the areas of the first electrode 14 and the second electrode 17 per first solar cell 11 similarly become large with only series connection. According to the embodiment, the series sub modules are electrically connected in parallel so that the areas of the transparent electrodes can be reduced. When the areas of the transparent electrodes are reduced, the parallel connection number also increases and a non-power generation region increases in size. Therefore, excessively reducing the areas of the transparent electrodes are unfavorable. Electricity generated by each cell flows in a width direction (a lateral direction) being the second direction of each solar cell. Therefore, shortening the distances of the transparent electrodes in the width direction can relax the influence of the resistance of the transparent electrodes. In consideration of the above, the widths of the first electrodes 14 and 24, the widths of the second electrodes 17 and 27, or the widths of the first electrodes 14 and 24 and the second electrodes 17 and 27, are preferably 3 to 15 mm, more preferably, 3.3 to 8 mm, and, further preferably, 3.5 to 8 mm. Note that, the widths of the first electrodes 14 and 24 are the distances of faces of the first electrodes 14 and 24 facing the substrates 13 and 23, respectively, in the second direction. Similarly, the widths of the second electrodes 17 and 27 are the distances of faces of the second electrodes 17 and 27 facing the substrates 13 and 23, respectively, in the second direction.

### Third Embodiment

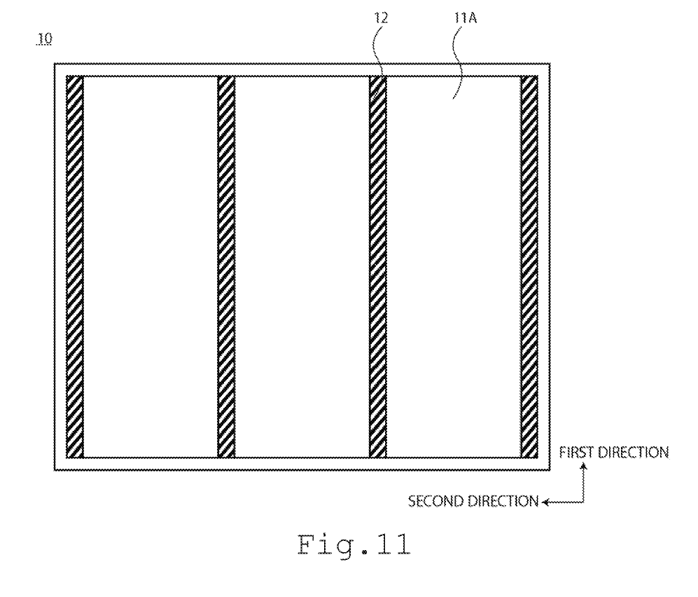

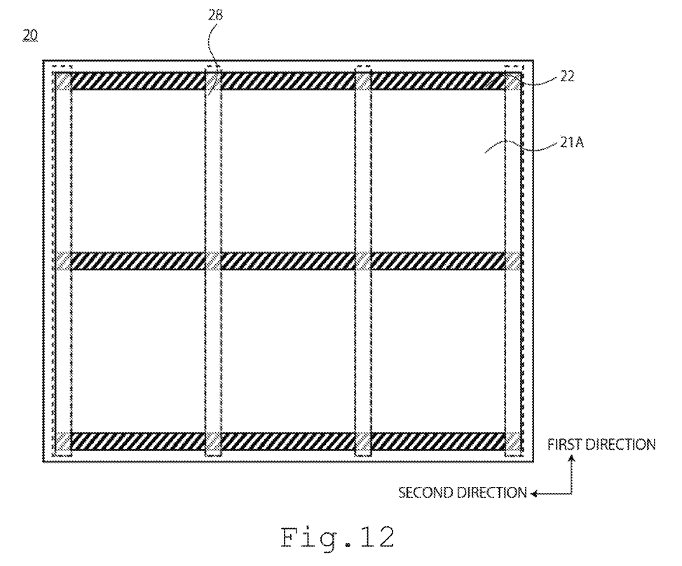

A solar module according to a third embodiment, includes a first solar panel and a second solar panel layered with the first solar panel, the first solar panel including a plurality of first submodules electrically connected with a busbar, the plurality of first submodules each including a plurality of first solar cells, the second solar panel including a plurality of second submodules electrically connected with a busbar, the plurality of second submodules each including a plurality of second solar cells. The two solar panels are preferably electrically connected in parallel. FIG. 11 illustrates a schematic view of the first solar panel 10 according to the third embodiment, and FIG. 12 illustrates a schematic view of the second solar panel 20 according to the third embodiment. The panels in FIGS. 11 and 12 have rectangular shapes the same size. The longitudinal direction of each of the first submodules 11A is the same as the longitudinal directions of the first solar cells in the first submodule 11A. The longitudinal direction of each of the second submodules 21A is the same as the longitudinal directions of the second solar cells in the second submodule 21A.

The first solar panel 10 in FIG. 11, includes the first submodules 11A each having the longitudinal direction in a first direction, arranged. The first busbar 12 is connected between the first submodules 11A and to both ends thereof, so that electric power generated by each of the first submodules 11A is extracted with the first busbar 12. Note that, the schematic view in FIG. 11 illustrates a set including a trio of the first submodules 11A electrically connected in parallel with the first busbar 12. For example, the first submodules 11A in number can be appropriately selected in accordance with the panel in size or shape.

The second solar panel 20 in FIG. 12, includes the second submodules 21A each having the longitudinal direction in a second direction, arranged. The second busbar 22 is connected between the second submodules 21A and to both ends thereof, so that electric power generated by each of the second submodules 21A is extracted with the second busbar 22. A region surrounded with a broken line in FIG. 12 indicates a region 28 in which the second solar panel 20 is covered with shade generated by the first busbar 12 when light is perpendicularly irradiated to the first solar panel 10. Note that, the schematic view in FIG. 12 illustrates a set including a pair of the second submodules 21A electrically connected in parallel with the second busbar 22. For example, the second submodules 21A in number can be appropriately selected in accordance with the panel in size or shape.

The first busbar 12 of the first solar panel 10 is provided astride the second solar cells 21 of the second solar panel 20. Therefore, the region 28 being the shade to all the second solar cells 21, is approximately equally provided to each of the second solar cells 21. An area portion of the region 28 being the shade to the second solar cells 21, is a non-power generation region. When the non-power generation region of each of the second solar cells 21 is equivalent to each other, influence on power generation in the second solar panel 20 can be reduced. For example, when the shade generated by the first busbar 12 completely covers one of the second solar cells 21, the power generation capacity of the second solar cell 21 becomes zero so that the power generation capacity of the submodule in which the second solar cell 21 having the power generation capacity of zero is connected in series, also becomes zero. However, when the shade generated by the first busbar 12 partially and equally covers the second solar cells 21, power generation capacity decreases on a similar level in each of the second solar cells 21 so that the power generation capacity of each of the second submodules 21A decreases by the area of the region that has been shaded. Even when the submodules disagree with each other in size or direction so as to have different directions to the busbar 12, the second solar cells 21 are barely shaded with the first busbar 12. Thus, the first solar panel 10 can have a configuration so as to make a large amount of the light reach a power generation region of the second solar panel 20. Even with the configuration, the first solar panel 10 and the second solar panel 20 can be connected in parallel with low loss with the first solar panel 10 and the second solar panel 20 agreeing with each other in power generation voltage.

### Fourth Embodiment

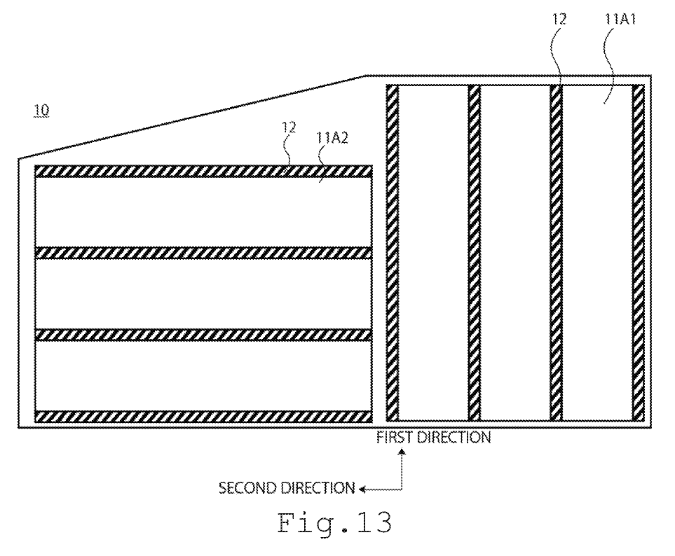

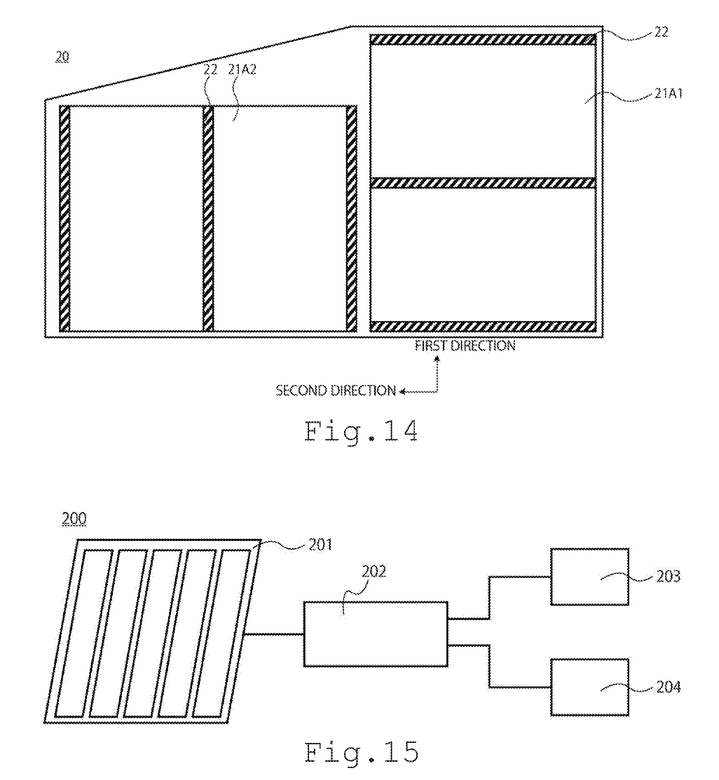

A solar module according to a fourth embodiment, includes a first solar panel and a second solar panel layered with the first solar panel, the first solar panel including a plurality of first submodules electrically connected with a busbar, the plurality of first submodules each including a plurality of first solar cells. The solar module according to the fourth embodiment is a modification of the solar module according to the third embodiment. The two solar panels are preferably electrically connected in parallel. FIG. 13 illustrates a schematic view of the first solar panel 10 according to the fourth embodiment, and FIG. 14 illustrates a schematic view of the second solar panel 20 according to the fourth embodiment. The panels in FIGS. 13 and 14 are trapezoid shapes the same size. In a case where a solar module is arranged, for example, on a roof, using the module according to the present embodiment can effectively expand the installation area of the solar module (an effective area) when a region for the arrangement is not rectangular.

The solar module according to the fourth embodiment, is in common with the solar module according to the third embodiment except the shape of the panels and the arrangement or configuration of the submodules.

In a case where the panel shape is trapezoid, when the submodules are arranged so as to have a longitudinal direction in one direction in each of the panels similarly to the third embodiment, the submodules partially protrude from the panel or a non-power generation region increases and thus the solar cells (the submodules) cannot be effectively arranged. Thus, the arrangements and configurations of the submodules are varied as illustrated in the schematic views in FIGS. 13 and 14 when the panel shape is, for example, trapezoid instead of being rectangular, so that the submodules can be effectively arranged on the panels.

In the first solar panel 10 illustrated in the schematic view in FIG. 13, a trio of the first submodules 11A1 each having a longitudinal direction in a first direction on the right side of the panel in the drawing and a trio of the first submodules 11A2 each having a longitudinal direction in a second direction on the left side of the panel in the drawing are combined together so that the trapezoid shape and the arrangement of the submodules correspond to each other. The trio of the submodules is electrically connected in parallel. The aspect ratio of the trio of the first submodules 11A connected in parallel is not one-to-one. The first submodule 11A is adjusted in any of size, aspect ratio, arrangement direction, number, and position so that the arrangement of the first submodules 11A corresponding to the shape of the panel can be made.

In the second solar panel 20 illustrated in the schematic view in FIG. 14, a pair of the second submodules 21A1 each having a longitudinal direction in the second direction on the right side of the panel in the drawing and a pair of the second submodules 21A2 each having a longitudinal direction in the first direction on the left side of the panel in the drawing are combined together so that the trapezoid shape and the arrangement of the submodules correspond to each other. The pair of the submodules is electrically connected in parallel. The aspect ratio of the pair of the second submodules 21A connected in parallel is not one-to-one. The second submodule 21A is adjusted in any of size, aspect ratio, arrangement direction, number, position so that the arrangement of the second submodules 21A corresponding to the shape of the panel can be made.

Even when the solar panels in FIGS. 13 and 14 are superimposed on each other, the busbar 12 of the first solar panel 10 inhibits influence of decreasing power generation capacity in each of the second solar cells 21 of the second solar panel 20, similarly to the third embodiment. Even when the submodules disagree with each other in direction so as to have different directions to the busbar 12, the second solar cells 21 are barely shaded with the busbar 12. Thus, the first solar panel 10 can have a configuration so as to make a large amount of light reach a power generation region of the second solar panel 20. Even with the configuration, the first solar panel 10 and the second solar panel 20 can be connected in parallel with low loss with the first solar panel 10 and the second solar panel 20 agreeing with each other in power generation voltage.

### Fifth Embodiment

Solar modules 100 and 101 (including third and fourth embodiments) according to the previous embodiments each can be used as a dynamo that generates electric power, in a photovoltaic power generation system according to a third embodiment. The photovoltaic power generation system according to the embodiment generates electric power with a solar module, and specifically has the solar module that generates the electric power, means for converting generated electricity into power, and a storage means for storing the generated electricity or a load that consumes the generates electricity. FIG. 11 is a conceptual diagram of a configuration of the photovoltaic power generation system 200 according to the embodiment. The photovoltaic power generation system 200 in FIG. 11 has the solar module 201 (100 or 101), the converter 202, the storage battery 203, and the load 204. Any one of the storage battery 203 and the load 204 may be omitted. The load 204 may have a configuration in which electric energy stored in the storage battery 203 can be used. The converter 202 is a device including a circuit or an element that performs power conversion, such as voltage transformation or DC-AC conversion, the device being a DC-DC converter, a DC-AC converter, or an AC-AC converter. The configuration of the converter 202 may adopt a suitable configuration in accordance with a configuration of the voltage of power generation, the storage battery 203, and the load 204.

Each solar cell included in the solar module 201, receives light and then generates electric power. After that, the electric energy thereof is converted by the converter 202 so as to be stored in the storage battery 203 or be consumed by the load 204. The solar module 201 preferably includes, for example, a sunlight-tracking drive device for controlling the solar module 201 to face sunlight, provided, a condenser that condenses the sunlight, provided, or a device for improving power generation efficiency, added.

The photovoltaic power generation system 200 is preferably used in real property, such as a dwelling, a commercial facility, or a factory, or in movable property, such as a vehicle, an aircraft, or an electric device. The photoelectric conversion element having excellent conversion efficiency, according to the embodiment, is applied to the solar module 201 so that an increase of power generation capacity can be expected.

The present disclosure will be specifically described below based on examples, but the present disclosure is not limited to the examples below.

### Example 1

According to Example 1, Cu_{0.95}GaSe_{1.82}S_{0.18} is used for a light-absorbing layer of each first solar cell of a first solar panel, and Cu_{0.95}In_{0.7}Ga_{0.3}Se₂ is used for a light-absorbing layer of each second solar cell of a second solar panel. The first solar panel and the second solar panel are 1650 mm in a first direction and 991 mm in second direction in size. Each first solar cell has a width of 4.5 mm, and the number of the first solar cells provided in a row in the second direction is 216. The number of the cells electrically connected in series is 72 so that three first submodules are formed. Total of four busbars each having a width of 3 mm are provided between the three first submodules, and at both ends thereof, so as to be electrically connected in parallel. Each second solar cell has a width of 3.5 mm, and the number of the second solar cells provided in a row in the second direction is 276. The number of the cells electrically connected in series is 138 so that two second submodules are formed. Total of three busbars each having a width of 3 mm are provided between the two second submodules, and at both ends thereof, so as to electrically be connected in parallel.

First, Jsc, Voc, and the conversion efficiency are acquired for the first solar panel and the second solar panel, individually. Sequentially, the first solar panel and the second solar panel are layered so as to be electrically connected in parallel so that the conversion efficiency of the solar module is acquired. The other examples and comparative examples are collectively shown in Table 1.

### Comparative Example 1

Each first solar cell has a width of 4.5 mm, and the number of the first solar cells provided in a row in the second direction is 216. The number of the cells electrically connected in series is 216 so that one first submodule is formed. Both sides of a panel each include a busbar provided so that each first solar cell is electrically connected in series. Each second solar cell has a width of 3.5 mm, and the number of the second solar cells provided in a row in the second direction is 276. The number of the cells electrically connected in series is 276 so that one second submodule is formed. Both sides of a panel each include a busbar provided so that each second solar cell is electrically connected in series. Comparative example 1 is similar to Example 1 except the above.

### Comparative Example 2

Each first solar cell has a width of 13.6 mm, and the number of the first solar cells provided in a row in a second direction is 72. The number of the cells electrically connected in series is 72 so that one first submodule is formed. Both sides of a panel each include a busbar provided so that each first solar cell is electrically connected in series. Each second solar cell has a width of 7.0 mm, and the number of the second solar cells provided in a row in the second direction is 138. The number of the cells electrically connected in series is 138 so that one second submodule is formed. Both sides of a panel each include a busbar provided so that each second solar cell is electrically connected in series. Comparative example 2 is similar to Example 1 except the above.

### Example 2

Each first solar cell has a width of 6.1 mm, and the number of the first solar cells provided in a row in a second direction is 159. The number of the cells electrically connected in series is 53 so that three first submodules are formed. Total four busbars are provided between the three first submodules, and at both ends thereof, so as to be electrically connected in parallel. Each second solar cell has a width of 4.8 mm, and the number of the second solar cells provided in a row in the second direction is 200. The number of the cells electrically connected in series is 100 so that two second submodules are formed. Total of three busbars are provided between the two second submodules, and both ends thereof, so as to be electrically connected in parallel. Example 2 is similar to Example 1 except the above.

### Example 3

Each first solar cell has a width of 8.4 mm, and the number of the first solar cells provided in a row in a second direction is 115. The number of the cells electrically connected in series is 23 so that five first submodules are formed. Total of six busbars are provided between the five first submodules, and at both ends thereof, so as to be electrically connected in parallel. Each second solar cell has a width of 11 mm, and the number of the second solar cells provided in a row in the second direction is 88. The number of the cells electrically connected in series is 44 so that two second submodules are formed. Total of three busbars are provided between the two second submodules, and both ends thereof, so as to be electrically connected in parallel. Example 3 is similar to Example 1 except the above.

### Example 4

Each first solar cell has a width of 8.4 mm, and the number of the first solar cells provided in a row in a second direction is 115. The number of the cells electrically connected in series is 23 so that five first submodules are formed. Total of six busbars are provided between the five first submodules, and at both ends thereof, so as to be electrically connected in parallel. Each second solar cell has a width of 7.4 mm, and the number of the second solar cells provided in a row in the second direction is 132. The number of the cells electrically connected in series is 44 so that three second submodules are formed. Total of four busbars are provided between the three second submodules, and both ends thereof, so as to be electrically connected in parallel. Example 4 is similar to Example 1 except the above.

### Example 5

Each first solar cell has a width of 13 mm, and the number of the first solar cells provided in a row in a second direction is 75. The number of the cells electrically connected in series is 25 so that three first submodules are formed. Total four busbars are provided between the three first submodules, and at both ends thereof, so as to be electrically connected in parallel. Each second solar cell has a width of 6.9 mm, and the number of the second solar cells provided in a row in the second direction is 141. The number of the cells electrically connected in series is 47 so that three second submodules are formed. Total of four busbars are provided between the three second submodules, and both ends thereof, so as to be electrically connected in parallel. Example 5 is similar to Example 1 except the above.

### Example 6

Each first solar cell has a width of 14 mm, and the number of the first solar cells provided in a row in a second direction is 69. The number of the cells electrically connected in series is 23 so that three first submodules are formed. Total four busbars are provided between the three first submodules, and at both ends thereof, so as to be electrically connected in parallel. Each second solar cell has a width of 7.4 mm, and the number of the second solar cells provided in a row in the second direction is 132. The number of the cells electrically connected in series is 44 so that three second submodules are formed. Total of four busbars are provided between the three second submodules, and both ends thereof, so as to be electrically connected in parallel. Example 6 is similar to Example 1 except the above.

### Example 7

Each first solar cell has a width of 15 mm, and the number of the first solar cells provided in a row in a second direction is 63. The number of the cells electrically connected in series is 21 so that three first submodules are formed. Total four busbars are provided between the three first submodules, and at both ends thereof, so as to be electrically connected in parallel. Each second solar cell has a width of 8.1 mm, and the number of the second solar cells provided in a row in the second direction is 120. The number of the cells electrically connected in series is 40 so that three second submodules are formed. Total of four busbars are provided between the three second submodules, and both ends thereof, so as to be electrically connected in parallel. Example 7 is similar to Example 1 except the above.

### Example 8

Cu_{0.95}GaSe₂ is used for a light-absorbing layer of each first solar cell of a first solar panel. Each first solar cell has a width of 5.4 mm, and the number of the first solar cells provided in a row in a second direction is 180. The number of the cells electrically connected in series is 60 so that three first submodules are formed. Total of four busbars are provided between the three first submodules, and both ends thereof, so as to be electrically connected in parallel. Cu_{0.96}In_{0.59}Ga_{0.41}Se₂ is used for a light-absorbing layer of each second solar cell of a second solar panel. Each second solar cell has a width of 5.9 mm, and the number of the second solar cells provided in a row in the second direction is 164. The number of the cells electrically connected in series is 82 so that two second submodules are formed. Total of three busbars are provided between the two second submodules, and both ends thereof, so as to be electrically connected in parallel. Example 8 is similar to Example 1 except the above. (Each second solar cell has Voc being 0.705 in a state where a top cell is present)

### Example 9

Cu_{0.95}GaSe₂ is used for a light-absorbing layer of each first solar cell of a first solar panel. Each first solar cell has a width of 6.1 mm, and the number of the first solar cells provided in a row in a second direction is 160. The number of the cells electrically connected in series is 80 so that two first submodules are formed. Total of three busbars are provided between the two first submodules, and both ends thereof, so as to be electrically connected in parallel. Cu_{0.96}In_{0.59}Ga_{0.41}Se₂ is used for a light-absorbing layer of each second solar cell of a second solar panel. Each second solar cell has a width of 4.5 mm, and the number of the second solar cells provided in a row in the second direction is 216. The number of the cells electrically connected in series is 108 so that two second submodules are formed. Total of three busbars are provided between the two second submodules, and both ends thereof, so as to be electrically connected in parallel. Example 9 is similar to Example 1 except the above.

### Example 10

CH₃NH₃Pb(I, Cl)₃ as a perovskite compound is used for a light-absorbing layer of each first solar cell of a first solar panel. Each first solar cell has a width of 8.1 mm, and the number of the first solar cells provided in a row in a second direction is 120. The number of the cells electrically connected in series is 40 so that three first submodules are formed. Total of four busbars are provided between the three first submodules, and both ends thereof, so as to be electrically connected in parallel. Cu_{0.96}In_{0.59}Ga_{0.41}Se₂ is used for a light-absorbing layer of each second solar cell of a second solar panel. Each second solar cell has a width of 7.8 mm, and the number of the second solar cells provided in a row in the second direction is 124. The number of the cells electrically connected in series is 62 so that two second submodules are formed. Total of three busbars are provided between the two second submodules, and both ends thereof, so as to be electrically connected in parallel. Example 10 is similar to Example 1 except the above.

### Example 11

Amorphous silicon is used for a light-absorbing layer of each first solar cell of a first solar panel. Each first solar cell has a width of 8.1 mm, and the number of the first solar cells provided in a row in a second direction is 120. The number of the cells electrically connected in series is 40 so that three first submodules are formed. Total of four busbars are provided between the three first submodules, and both ends thereof, so as to be electrically connected in parallel. Cu_{0.96}In_{0.59}Ga_{0.41}Se₂ is used for a light-absorbing layer of each second solar cell of a second solar panel. Each second solar cell has a width of 6.2 mm, and the number of the second solar cells provided in a row in the second direction is 156. The number of the cells electrically connected in series is 52 so that three second submodules are formed. Total of four busbars are provided between the three second submodules, and both ends thereof, so as to be electrically connected in parallel. Example 11 is similar to Example 1 except the above.

### Example 12

Amorphous silicon is used for a light-absorbing layer of each first solar cell of a first solar panel. Each first solar cell has a width of 8.1 mm, and the number of the first solar cells provided in a row in a second direction is 120. The number of the cells electrically connected in series is 40 so that three first submodules are formed. Total of four busbars are provided between the three first submodules, and both ends thereof, so as to be electrically connected in parallel. Cu_{0.96}In_{0.59}Ga_{0.41}Se₂ is used for a light-absorbing layer of each second solar cell of a second solar panel. Each second solar cell has a width of 9.4 mm, and the number of the second solar cells provided in a row in the second direction is 104. The number of the cells electrically connected in series is 52 so that two second submodules are formed. Total of three busbars are provided between the two second submodules, and both ends thereof, so as to be electrically connected in parallel. Example 12 is similar to Example 1 except the above.

### Example 13

Amorphous silicon is used for a light-absorbing layer of each first solar cell of a first solar panel. Each first solar cell has a width of 8.1 mm, and the number of the first solar cells provided in a row in a second direction is 120. The number of the cells electrically connected in series is 40 so that three first submodules are formed. Total of four busbars are provided between the three first submodules, and both ends thereof, so as to be electrically connected in parallel. Cu_{1.87}Zn_{1.02}Sn_{0.99}Se_{0.07}S_{3.93} is used for a light-absorbing layer of each second solar cell of a second solar panel. Each second solar cell has a width of 6.8 mm, and the number of the second solar cells provided in a row in the second direction is 144. The number of the cells electrically connected in series is 72 so that two second submodules are formed. Total of three busbars are provided between the two second submodules, and both ends thereof, so as to be electrically connected in parallel. Example 13 is similar to Example 1 except the above.

TABLE 1A

| | FIRST SOLAR PANEL | | |
|---|---|---|---|
| | | | CONVERSION |
| | Jsc A | Voc V | EFFICIENCY % |
| EXAMPLE 1 | 2.8 | 92.2 | 12.4 |
| COMPARATIVE | 0.9 | 276.5 | 12.4 |
| EXAMPLE 1 | | | |
| COMPARATIVE | 2.8 | 91.5 | 12.2 |
| EXAMPLE 2 | | | |
| EXAMPLE 2 | 3.8 | 67.8 | 12.4 |
| EXAMPLE 3 | 8.7 | 29.4 | 12.3 |
| EXAMPLE 4 | 8.7 | 29.4 | 12.3 |
| EXAMPLE 5 | 8.0 | 31.8 | 12.2 |
| EXAMPLE 6 | 8.7 | 29.2 | 12.1 |
| EXAMPLE 7 | 9.3 | 26.5 | 11.6 |
| EXAMPLE 8 | 3.7 | 57.0 | 10.1 |
| EXAMPLE 9 | 2.8 | 76.0 | 10.1 |
| EXAMPLE 10 | 9.3 | 43.2 | 18.1 |
| EXAMPLE 11 | 6.5 | 35.2 | 8.9 |
| EXAMPLE 12 | 6.5 | 35.2 | 8.9 |
| EXAMPLE 13 | 6.5 | 35.2 | 8.9 |

TABLE 1B

| | SECOND SOLAR PANEL | | | SOLAR |
|---|---|---|---|---|
| | MOUNTED WITH FIRST | | | MODULE |
| | SOLAR PANEL | | | TOTAL |
| | | | CONVERSION | CONVERSION |
| | Jsc A | Voc V | EFFICIENCY % | EFFICIENCY % |
| EXAMPLE 1 | 2.9 | 93.8 | 12.7 | 24.6 |
| COMPARATIVE | 1.4 | 187.7 | 12.7 | 16.7 |
| EXAMPLE 1 | | | | |
| COMPARATIVE | 2.9 | 93.7 | 12.5 | 24.2 |
| EXAMPLE 2 | | | | |
| EXAMPLE 2 | 3.9 | 68.0 | 12.6 | 24.6 |
| EXAMPLE 3 | 9.0 | 29.9 | 12.4 | 24.2 |
| EXAMPLE 4 | 9.1 | 29.9 | 12.6 | 24.6 |
| EXAMPLE 5 | 8.5 | 31.9 | 12.6 | 23.5 |
| EXAMPLE 6 | 9.1 | 29.9 | 12.6 | 23.1 |
| EXAMPLE 7 | 9.9 | 27.0 | 12.3 | 22.2 |
| EXAMPLE 8 | 4.0 | 57.8 | 10.8 | 18.8 |
| EXAMPLE 9 | 3.0 | 76.1 | 10.8 | 18.8 |
| EXAMPLE 10 | 2.6 | 43.0 | 5.1 | 21.9 |
| EXAMPLE 11 | 6.0 | 36.6 | 10.4 | 18.3 |
| EXAMPLE 12 | 6.1 | 36.5 | 10.5 | 18.2 |
| EXAMPLE 13 | 1.0 | 36.7 | 1.4 | 9.4 |

The parallel numbers of the first submodules and the second submodules are optimized so that the efficiency increases.

Widening the width of scribing in order to forcibly make the parallel numbers in agreement, decreases the efficiency of a single body. Therefore, the total efficiency (output) decreases.

A difference between a band gap of the light absorbing layer of the first solar cell and a band gap of the light absorbing layer of the second solar cell can be increased by using Cu₂O, (Cd, Zn, Mg) (Te, Se, S), (In, Ga)₂(S, Se, Te)₃, having very wider band gap, as a light absorbing layer of the first solar cell. When the difference between the band gap of the light absorbing layer of the first solar cell and a band gap of the light absorbing layer of the second solar cell increases, the power generation increases because light that contributes to the power generation in the light absorbing layer of the second solar cell increases. By applying such multi-junction solar cell having large difference between the band gaps and also applying the connecting mode of the solar cells, the power generation in the second solar panel on the bottom side, increasing the power generation in the multi-junction solar cell is expected. Here, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar module comprising:
a first solar panel having a plurality of first submodules each including a plurality of first solar cells; and
a second solar panel layered with the first solar panel, the second solar panel having a plurality of second submodules each including a plurality of second solar cells,
wherein the first solar panel is provided on a side where light is incident,
the first solar panel and the second solar panel are electrically connected in parallel,
the plurality of first solar cells included in each of the plurality of first submodules is electrically connected in series,
the plurality of first submodules is electrically connected in parallel,
the plurality of second solar cells included in each of the plurality of second submodules is electrically connected in series, and
the plurality of second submodules is electrically connected in parallel.

2. The module according to claim 1, wherein the plurality of first solar cells each having a structure in which a longitudinal direction is a first direction,
the plurality of first solar cells included in each of the first submodules is electrically connected in series in a second direction,
the plurality of first submodules is electrically connected in parallel in the second direction,
the plurality of second solar cells each has a structure in which a longitudinal direction is the first direction,
the plurality of second solar cells included in each of the second submodules is electrically connected in series in the second direction, and
the second plurality of submodules is electrically connected in parallel in the second direction.

3. The module according to claim 1, wherein a difference between an output voltage of the first solar panel and an output voltage of the second solar panel, is 2.0 V or less.

4. The module according to claim 1, wherein the plurality of first solar cells each has a light-absorbing layer including at least one type selected from the group consisting of: a compound semiconductor, a perovskite compound, a transparent oxide semiconductor, and amorphous silicon.

5. The module according to claim 1, wherein the plurality of second solar cells each has a light-absorbing layer including one selected from the group consisting of: a compound semiconductor, a transparent oxide semiconductor, a perovskite compound, and a compound including Ge.

6. The module according to claim 1, wherein a band gap of a light absorbing layer of the second solar cell is narrower than that of a light absorbing layer of the first solar cell.

7. The module according to claim 1, wherein the plurality of first solar cells included in each of the first submodules, is different from the plurality of second solar cells included in each of the second submodules, in series connection number.

8. The module according to claim 1, wherein the plurality of first submodules is electrically connected in parallel with a busbar, and
the plurality of second submodules is electrically connected in parallel with a busbar.

9. The module according to claim 8, wherein the busbar of the first solar panel is provided on both ends of the first solar panel.

10. The module according to claim 8, wherein a first direction and a second direction intersect each other,
the plurality of first solar cells each has a structure in which a longitudinal direction is the first direction,
the plurality of first submodules is electrically connected in parallel in the second direction,
the plurality of first solar cells included in each of the first submodules is electrically connected in series in the second direction,
the plurality of second solar cells each have a structure in which a longitudinal direction is the first direction,
the plurality of second submodules is electrically connected in parallel in the second direction,
the plurality of second solar cells included in each of the second submodules is electrically connected in series in the second direction, and
the busbars of the first solar panel and the second solar panel each have a longitudinal direction in the first direction.

11. A solar module comprising:
a first solar panel having a plurality of first submodules electrically connected with a busbar, the plurality of first submodules each including a plurality of first solar cells; and
a second solar panel layered with the first solar panel, the second solar panel including a plurality of second submodules electrically connected with a busbar, the plurality of second submodules each including a plurality of second solar cells.

12. A photovoltaic power generation system comprising:
the solar module according to claim 1.

13. A photovoltaic power generation system comprising:
the solar module according to claim 11.
